(19) United States
(12) Patent Application Publication
(10) Pub. No.: US 2016/0326008 A1
(43) Pub. Date: Nov. 10, 2016

(54) INDIUM-CONTAINING FILM AND COMPOSITION FOR FORMING THE SAME

(71) Applicant: UP CHEMICAL CO., LTD., Pyeongtaek-si (KR)

(72) Inventors: Wonyong Koh, Daejeon (KR); Byungsoo Kim, Daejeon (KR); Dong Hwan Ma, Seoul (KR)

(21) Appl. No.: 15/214,163

(22) Filed: Jul. 19, 2016

Related U.S. Application Data
(63) Continuation-in-part of application No. 14/339,640, filed on Jul. 24, 2014, now Pat. No. 9,431,144.
Application No. 14/339,640 is a continuation of application No. PCT/KR2013/000678, filed on Jan. 28, 2013.

(30) Foreign Application Priority Data
Jan. 27, 2012 (KR) 10-2012-0008340
Nov. 7, 2012 (KR) 10-2012-0125552
Jan. 28, 2013 (KR) 10-2013-0009168

(51) Int. Cl. C01G 15/00; H01L 29/24; H01L 29/786; C09D 5/24; G02F 1/1343; C23C 16/40; C23C 16/455; H01B 1/08; H01L 21/02

(52) U.S. Cl. CPC C01G 15/00; H01B 1/08; H01L 29/24; H01L 29/7869; H01L 21/02565; H01L 21/0262; G02F 1/13439; C23C 16/407; C23C 16/45531; C23C 16/45553; C09D 5/24; H01L 21/02381; H01L 21/02422; C01P 2006/40

(57) ABSTRACT

The present invention relates to an indium-containing film formed by reacting a gas containing an indium precursor with an oxygen-containing gas on a substrate, and to a composition for forming the indium-containing film. Using chemical vapor deposition or atomic layer deposition, when a particular indium precursor is used, an indium-containing film having high conductivity and high quality can be formed on a substrate having a large area, and particularly a substrate for manufacturing a display device.

### CROSS-REFERENCE TO RELATED APPLICATIONS

This application is a continuation-in-part of U.S. patent application Ser. No. 14/339,640 filed on Jul. 24, 2014 which is a continuation application of International Application No. PCT/KR2013/000678 filed Jan. 28, 2013, claiming priority based on Korean Patent Application No. 10-2012-0008340 filed on Jan. 27, 2012, No. 10-2012-0125552 filed on Nov. 7, 2012, and No. 10-2013-0009168 filed on Jan. 28, 2013 in the Korean Intellectual Property Office, the entire disclosure of all of which are incorporated herein by reference for all purposes.

### TECHNICAL FIELD

The embodiments described herein pertain generally to an indium-containing film and a composition for forming an indium-containing film.

### BACKGROUND

An indium-containing oxide is transparent and conducts electricity, and thus has been widely used in the industry. Due to a higher conductivity or other advantages, a composite indium oxide film containing indium and other metals or an indium oxide film doped with other elements such as fluorine are commonly used rather than an indium oxide film containing indium only. By way of example, an indium tin oxide (ITO) has been used as an electrode of a liquid crystal display (LCD) for a long time. In recent years, researches for using an oxide (In—Ga—Zn—O, IGZO) containing indium, gallium, and zinc in a transparent thin film transistor have been actively carried out. In addition to Sn, Ga, and Zn, other metals such as Al and Mg, and so on also may be used in a composite oxide film containing indium. Most of ITO films used in the current industry have been prepared by a sputtering method. As described in International Patent Application Publication No. WO2010/024279 (Korean Patent Publication No. 10-2011-0028393), an IGZO film has been also generally prepared by a sputtering method.

Chemical vapor deposition (CVD) or atomic layer deposition (ALD) in which source gases are alternately brought into contact with a substrate has an advantage of being able to form a film having a uniform thickness on an uneven surface.

Elam et al. reported a method for forming In₂O₃ and ITO films by atomic layer deposition using cyclopentadienyl indium (Cpin) which is a solid at a room temperature [J. W. Elam et al., “Atomic Layer Deposition of In₂O₃ Using Cyclopentadienyl Indium: A New Synthetic Route to Transparent Conducting Oxide Films”, Chemistry of Materials, Volume 18, p3571 (2006); J. W. Elam et al., “Atomic Layer Deposition of Indium Tin Oxide Thin Films Using Nonhalogenated Precursors” Journal of Physical Chemistry C, volume 112, p1938 (2008)]. It is very difficult to vaporize a solid compound and supply it to a large-area substrate at a uniform concentration, and, thus, it is difficult to industrially apply a method for forming In₂O₃ and ITO films on a large-area substrate using Cpin as an indium source.

There have been known methods for forming an indium oxide film or an indium-containing oxide film by chemical vapor deposition or atomic layer deposition using other indium compounds instead of Cpin as a source material. Ritala et al. reported a method for forming an indium oxide film or an ITO film by atomic layer deposition using InCl₃ and SnCl₄ [M. Ritala et al., “Enhanced Growth Rate in Atomic Layer Epitaxy of Indium Oxide and Indium-Tin Oxide Thin Films”, Electrochemical and Solid-State Letters, volume 1, p156 (1998)]. InCl₃ is a solid at a room temperature, and in order to supply InCl₃ in a gaseous state, a source supply unit needs to be heated at a high temperature of 285° C. Mikko Rit et al. reported a method for forming a conductive indium oxide film, ITO, and an indium oxide film doped with fluorine using In(hfac)₃, In(thd)₃, and In(acac)₃ which are solids at a room temperature (hfac=hexafluoropentadionate; thd=2,2,6,6-tetramethyl-3,5-heptanedionate; acac=2,4-pentanedionate) [Mikko Rit et al., “ALE Growth of Transparent Conductors”, Material Research Society Symposium Proceedings, volume 426, p513 (1996)]. Nielsen et al. reported a method for forming an indium oxide film by atomic layer deposition using In(acac)₃ [O. Nielsen et al., “Thin films of In₂O₃ by atomic layer deposition using In(acac)₃”, Thin Solid Films, volume 517, p6320 (2009)]. Ott et al. reported a method for forming an indium oxide film using In(CH₃)₃ which is a solid at a room temperature [A. W. Ott et al., “Surface chemistry of In₂O₃ deposition using In(CH₃)₃ and H₂O in a binary reaction sequence”, Applied Surface Science, volume 112, p205 (1997)]. Jin Ho Park et al. reported a method for forming an indium oxide film using [(CH₃)₂In(acac)]₂ which is a solid at a room temperature [J.-H. Park et al., “The X-ray single crystal structure of [Me₂In(acac)]₂ and its use as a single-source precursor for the deposition of indium oxide thin films”, Journal of Materials Chemistry, volume 11, p2346 (2001)]. Gaskell and Sheel also reported a method for forming an indium oxide film doped with fluorine using [(CH₃)₂In(acac)]₂ [D. W. Sheel and J. M. Gaskell, “Deposition of fluorine doped indium oxide by atmospheric pressure chemical vapour deposition”, Thin Solid Films, volume 520, p1242 (2011)]. Barry et al. reported a method for forming an indium oxide film by chemical vapor deposition using In[(NⁱPr)₂CN(CH₃)₂]₃ which is a solid at a room temperature, as a source material [S. T. Barry et al., “Chemical vapour deposition of In₂O₃ thin films from a tris-guanidinate indium precursor”, Dalton Transactions, volume 40, p9425 (2011)].

So far, all of the indium sources used for forming indium oxide films or indium-containing oxide films are solids at a room temperature. There has not been known a method for forming an indium oxide film or an indium-containing oxide film by chemical vapor deposition or atomic layer deposition using an indium compound which is a liquid at a room temperature. Further, there has not been known an example of forming, via chemical vapor deposition or atomic layer deposition, indium oxide film or indium-containing oxide film having a high conductivity equivalent to that of an indium-containing oxide film formed by a sputtering method so as to be used as a transparent electrode.

A thin film transistor using IGZO is higher in speed than a thin film transistor using a non-crystalline silicon, and, thus, researches for applying it to a large-area LCD panel such as a TV, and so on have been actively carried out. It is necessary to form IGZO by chemical vapor deposition or atomic layer deposition in order to control a composition of an IGZO oxide film, but it is very difficult to form an indium oxide film or indium-containing oxide film on a display glass substrate even larger than 1 meter in width and length using a source material which is a solid at a room temperature.

In order to form an IGZO film on a large-area substrate, especially a large-area display substrate which can be applied to a TV, and so on, it is necessary to form an indium oxide film or indium-containing oxide film by chemical vapor deposition or atomic layer deposition using a liquid indium compound. In particular, in the case of using a glass substrate, it is necessary to form an indium oxide film or indium-containing oxide film by chemical vapor deposition or atomic layer deposition using a liquid indium compound at a temperature of 200° C. or less.

### DETAILED DESCRIPTION OF THE INVENTION

### Problems to be Solved by the Invention

In view of the foregoing problems, one purpose of the present disclosure is to provide an indium-containing film formed by a gas containing an indium precursor with an oxygen-containing gas on a substrate.

Another purpose of the present disclosure is also to provide a substrate including an indium-containing film.

Another purpose of the present disclosure is to provide an indium-containing film having a low resistivity.

Another purpose of the present disclosure is to provide a film consisting of an indium compound having a low resistivity.

Another purpose of the present disclosure is to provide a composition for forming an indium-containing film, including an indium precursor.

However, problems to be solved by the example embodiments of the present disclosure are not limited to the above-described problems. Although not described herein, other problems to be solved by the present disclosure can be clearly understood by those skilled in the art from the following descriptions.

### Means for Solving the Problems

In a first aspect of the present disclosure, there is provided an indium-containing film, formed by reacting a gas containing an indium precursor with an oxygen-containing gas.

In a second aspect of the present disclosure, there is provided a substrate including the indium-containing film in accordance with the first aspect.

In a third aspect of the present disclosure, there is provided an indium-containing film having a resistivity of 2×10⁻⁵ Ω·cm or less.

In a fourth aspect of the present disclosure, there is provided a film substantially consisting of an indium compound having a resistivity of 1×10⁻⁴ Ω·cm or less.

In a fifth aspect of the present disclosure, there is provided a composition for forming an indium-containing film, including an indium precursor.

### Effects of the Invention

Conventional indium precursor compounds used for forming indium-containing films are solids at a room temperature, and, thus, in order to supply the indium precursor compounds in a gaseous state when films are prepared, they need to be heated at a high temperature, and it is very difficult to vaporize the solids and supply them to a large-area substrate at a uniform concentration. However, an indium precursor compound according to the present disclosure for preparing an indium-containing film is a liquid at a room temperature and thus can be easily vaporized and can be supplied to a large-area substrate at a uniform concentration.

By using a method of the present disclosure, an indium-containing film can be easily formed on a substrate. In particular, by using a method of the present disclosure, an indium-containing film having a low resistivity, i.e. having a high conductivity with high purity can be easily formed. By using a method of the present disclosure, the indium-containing films such as an IGZO film as an oxide film containing indium, gallium, and zinc can be easily formed and the IGZO film has high purity and used for preparing a transparent thin film transistor in a display device. Further, an ITO used as a transparent conductive film can be formed to have an unexpectedly, significantly low resistivity, i.e. an unexpectedly, significantly high conductivity by using a method of the present disclosure. Further, by a method of the present disclosure, an indium-containing film can be formed on a large-areas substrate, for example, a large-area glass or polymer substrate. The polymer substrate may be a flexible substrate and can be used in the form of a roll.

### BRIEF DESCRIPTION OF THE DRAWINGS

FIG. 1 shows a Hall mobility and a carrier concentration of an indium oxide film in accordance with an example of the present disclosure.

FIG. 2 shows a resistivity of an indium oxide film in accordance with an example of the present disclosure.

### BEST MODE FOR CARRYING OUT THE INVENTION

Hereinafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways. In drawings, parts irrelevant to the description are omitted for the simplicity of explanation, and like reference numerals denote like parts through the whole document of the present disclosure.

Through the whole document of the present disclosure, the term “connected to” or “coupled to” that is used to designate a connection or coupling of one element to another element includes both a case that an element is “directly connected or coupled to” another element and a case that an element is “electronically connected or coupled to” another element via still another element.

Through the whole document of the present disclosure, the term “on” that is used to designate a position of one element with respect to another element includes both a case that the one element is adjacent to the another element and a case that any other element exists between these two elements.

Through the whole document of the present disclosure, the term “comprises or includes” and/or “comprising or including” used in the document means that one or more other components, steps, operation and/or existence or addition of elements are not excluded in addition to the described components, steps, operation and/or elements unless context dictates otherwise. The term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party. Through the whole document, the term “step of” does not mean “step for”.

Through the whole document of the present disclosure, the term “combinations of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Hereinafter, an indium-containing film of the present disclosure will be explained in detail with reference to embodiments, examples, and drawings. However, the present disclosure is not limited to the following embodiments, examples, and drawings.

In an example embodiment of the present disclosure, there is provided a method for forming an indium-containing film, including: providing a gas of an indium precursor and an oxygen-containing gas to a substrate to be reacted.

In an example embodiment of the present disclosure, the indium precursor may be a liquid at a room temperature and may include a member selected from the group consisting of bis(trimethylsilyl)aminodiethylindium [(CH₃CH₂)₂InN[Si(CH₃)₃]₂; Et₂InN(TMS)₂; herein, TMS means Si(CH₃)₃], dimethyl(3-dimethylaminopropyl)indium [(CH₃)₂In(CH₂)₃N(CH₃)₂; Me₂In(CH₂)₃NMe₂], and combinations thereof which can be easily vaporized, but may not be limited thereto. By way of example, Et₂InN(TMS)₂ has a vapor pressure of about 4.5 torr at about 100° C., and Me₂In(CH₂)₃NMe₂ has a vapor pressure of about 2.7 torr at about 50° C., and thus they are suitable to be used as a source material in chemical vapor deposition or atomic layer deposition. The above-described indium precursors are liquids at a room temperature and thus can be easily vaporized at a relatively low temperature, and they can be provided to a substrate at a uniform concentration and thus can be applied to a large-area substrate.

In an example embodiment of the present disclosure, the oxygen-containing gas may include a gas selected from the group consisting of H₂O, H₂O₂, O₂, O₃, and combinations thereof, but may not be limited thereto.

In an example embodiment of the present disclosure, the substrate may be a substrate having a large area, for example, about 1 m or more in width and length, respectively, but may not be limited thereto. By way of example, the substrate having a large area may be about 1 m or more, about 2 m or more, about 3 m or more, about 4 m or more, about 5 m or more, about 6 m or more, about 7 m or more, about 8 m or more, about 9 m or more, or about 10 m or more in width and length, respectively, but may not be limited thereto.

In an example embodiment of the present disclosure, the substrate may be employed from those used in the art without specific limitation. By way of example, the substrate may include a glass, silicon, silicon oxide, or a polymer, but may not be limited thereto.

In an example embodiment of the present disclosure, the substrate may be a glass substrate having a large area, but may not be limited thereto. Further, the substrate may be a substrate containing a polymer, but may not be limited thereto. By way of example, the substrate containing a polymer may have a type winded in the form of a roll as a flexible substrate, but may not be limited thereto. In an example embodiment of the present disclosure, the substrate containing a polymer may be a substrate containing a heat-resistant polymer, but may not be limited thereto. By way of example, the polymer may include a member selected from the group consisting of polyester (PET), polyethylenenapthalate (PEN), polycarbonate (PC), polyetherimide (PEI), polyethersulfone (PES), polyetheretherketon (PEEK), and polyimide, but may not be limited thereto.

In an example embodiment of the present disclosure, the substrate may be maintained at a temperature of from room temperature to about 500° C., for example, from room temperature to about 450° C., from room temperature to about 400° C., from room temperature to about 350° C., from room temperature to about 300° C., from room temperature to about 250° C., from room temperature to about 200° C., from about 50° C. to about 500° C., from about 50° C. to about 450° C., from about 50° C. to about 400° C., from about 50° C. to about 350° C., from about 50° C. to about 300° C., from about 50° C. to about 250° C., from about 50° C. to about 200° C., from about 50° C. to about 150° C., from about 100° C. to about 500° C., from about 100° C. to about 450° C., from about 100° C. to about 400° C., from about 100° C. to about 350° C., from about 100° C. to about 300° C., from about 100° C. to about 250° C., from about 100° C. to about 200° C., from about 100° C. to about 150° C., from about 150° C. to about 500° C., from about 150° C. to about 450° C., from about 150° C. to about 400° C., from about 150° C. to about 350° C., from about 150° C. to about 300° C., from about 150° C. to about 250° C., from about 150° C. to about 200° C., from about 175° C. to about 500° C., from about 175° C. to about 450° C., from about 175° C. to about 400° C., from about 175° C. to about 350° C., from about 175° C. to about 300° C., from about 175° C. to about 250° C., from about 175° C. to about 200° C., from about 200° C. to about 500° C., from about 200° C. to about 450° C., from about 200° C. to about 400° C., from about 200° C. to about 350° C., from about 200° C. to about 300° C., from about 200° C. to about 250° C., from about 225° C. to about 500° C., from about 225° C. to about 450° C., from about 225° C. to about 400° C., from about 225° C. to about 350° C., from about 225° C. to about 300° C., or from about 225° C. to about 250° C., but may not be limited thereto.

By way of example, in the case of using Et₂InN(TMS)₂ as the indium precursor, the substrate may be maintained at a temperature of from about 175° C. to about 300° C., but may not be limited thereto. By way of example, in the case of using Me₂In(CH₂)₃NMe₂ as the indium precursor, the substrate may be maintained at a temperature of from about 225° C. to about 300° C., but may not be limited thereto.

In an example embodiment of the present disclosure, the indium-containing film may include an indium-containing oxide film. For example, the indium-containing oxide film includes an indium oxide film.

In an example embodiment of the present disclosure, the indium-containing film consists of or substantially consists of an indium-containing oxide film. For example, the indium-containing oxide film consists of or substantially consists of an indium oxide.

In an example embodiment of the present disclosure, a resistivity of the indium-containing film or the indium-containing oxide film may be at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In an example embodiment of the present disclosure, in the case of using Et₂InN(TMS)₂ as the indium precursor, a resistivity of the indium-containing film may be about 1.6×10⁻⁵ Ω·cm, in the case of using Me₂ln(CH₂)₃NMe₂ as the indium precursor, a resistivity of the indium-containing film may be about 9.2×10⁻⁵ Ω·cm, but may not be limited thereto. The resistivity of the indium-containing film in accordance with an example embodiment of the present disclosure is decreased by about 50 times or more, about 100 times or more, about 500 times or more, about 1,000 times or more, or about 5,000 times or more as compared with resistivities of indium-containing films prepared using conventional indium precursors, which indicates that a conductivity of the indium-containing film in accordance with an example embodiment of the present disclosure is greatly improved.

In an example embodiment of the present disclosure, the indium-containing film does not include or does not substantially include Si derived from the indium precursor. Conventionally, when an indium precursor including Si element reacts with the oxygen-containing gas such as O₂, O₃, H₂O₂, H₂O and the like, it is typically expected to form a film including Indium, carbon, silicon and nitrogen. In this regard, Si included in the indium precursor reacts with the oxygen-containing gas to form SiO₂ which is an insulator so that it is conventionally expected that the film including SiO₂ has high electrical resistance, and thus low electrical conductivity. However, although the indium precursor used in embodiments of the present disclosure includes Indium, carbon, hydrogen, silicon and nitrogen elements, the indium-containing film produced by using the indium precursor does not include or does not substantially include Si derived from the indium precursor, which is a very significant result, unexpected in the art. Furthermore, the indium-containing film of the present disclosure includes very low carbon content. Conventionally, a film including carbon has poor electrical properties. Therefore, the indium-containing film of the present disclosure has unexpected superior electrical properties. In another example embodiment of the present disclosure, the indium-containing film does not include or does not substantially include other elements than indium, oxygen, and carbon, but may not be limited thereto. In further another embodiment of the present disclosure, the indium-containing film does not include or does not substantially include other elements than indium, oxygen, and less than about 1 at % carbon, but may not be limited thereto.

In an example embodiment of the present disclosure, the indium-containing film may be formed by chemical vapor deposition or atomic layer deposition, but may not be limited thereto. By the chemical vapor deposition or atomic layer deposition, a source in a gaseous state is supplied to a substrate, and, thus, a film having a uniform thickness can be formed on an uneven surface, and the source gas is supplied at a uniform concentration to a large-area substrate or a substrate in the form of a roll, and, thus, a uniform film can be formed. In the case of using the atomic layer deposition, a typical time division atomic layer deposition apparatus configured to supply each source gas in sequence may be used. Otherwise, there may be used a space division atomic layer deposition apparatus with reciprocating manner of a substrate between a region where one kind of a source gas needed for atomic layer deposition is filled and a region where another kind of a source gas is filled. If the substrate is a polymer substrate in the form of a roll, there may be used a roll-to-roll chemical vapor deposition apparatus or a roll-to-roll atomic layer deposition apparatus configured to unwind the roll to expose a surface of the substrate and then rewind in form of the roll on which a film is formed. The chemical vapor deposition or atomic layer deposition may be plasma enhanced chemical vapor deposition (PECVD) or plasma enhanced atomic layer deposition (PEALD) using plasma, but may not be limited thereto. Generally, plasma enhanced chemical vapor deposition or plasma enhanced atomic layer deposition has an advantage of being able to form a high-quality film at a lower film formation temperature as compared with the methods without using plasma.

In a first aspect of the present disclosure, there is provided an indium-containing film, formed by reacting a gas containing an indium precursor with an oxygen-containing gas.

In an example embodiment of the present disclosure, the indium precursor is a liquid at a room temperature.

In an example embodiment of the present disclosure, the indium-containing film may include an indium-containing oxide film. For example, the indium-containing oxide film includes an indium oxide.

In an example embodiment of the present disclosure, the indium-containing film consists of or substantially consists of an indium-containing oxide film. For example, the indium-containing oxide film consists of or substantially consists of an indium oxide.

In an example embodiment of the present disclosure, the indium precursor includes a member selected from the group consisting of Et₂InN(TMS)₂, Me₂In(CH₂)₃NMe₂, and combinations thereof, but may not be limited thereto.

In an example embodiment of the present disclosure, the oxygen-containing gas may include a gas selected from the group consisting of H₂O, H₂O₂, O₂, O₃, and combinations thereof, but may not be limited thereto.

In an example embodiment of the present disclosure, a resistivity of the indium-containing film or the indium-containing oxide film is at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In an example embodiment of the present disclosure, in the case of using Et₂InN(TMS)₂ as the indium precursor, a resistivity of the indium-containing film may be about 1.6×10⁻⁵ Ω·cm, in the case of using Me₂In(CH₂)₃NMe₂ as the indium precursor, a resistivity of the indium-containing film may be about 9.2×10⁻⁵ Ω·cm, but may not be limited thereto. A value of the resistivity of the indium-containing film in accordance with an example embodiment of the present disclosure is decreased by about 50 times or more, about 100 times or more, about 500 times or more, about 1,000 times or more, or about 5,000 times or more as compared with resistivities of indium-containing films formed by using conventional indium precursors, which indicates that a conductivity of the indium-containing film in accordance with an example embodiment of the present disclosure is greatly improved.

In an example embodiment of the present disclosure, the indium-containing film does not include or does not substantially include Si derived from the indium precursor. Conventionally, when an indium precursor including Si element reacts with the oxygen-containing gas such as O₂, O₃, H₂O₂, H₂O and the like, it is typically expected to form a film including Indium, carbon, silicon, and nitrogen. In this regard, Si included in the indium precursor reacts with the oxygen-containing gas to form SiO₂ which is an insulator so that it is conventionally expected that the film including SiO₂ has high electrical resistance, and thus low electrical conductivity. However, although the indium precursor used in embodiments of the present disclosure includes Indium, carbon, hydrogen, silicon, and nitrogen elements, the indium-containing film produced by using the indium precursor does not include or does not substantially include Si derived from the indium precursor, which is a very significant result, unexpected in the art. Furthermore, the indium-containing film of the present disclosure includes very low carbon content. Conventionally, a film including carbon has poor electrical properties. Therefore, the indium-containing film of the present disclosure has unexpected superior electrical properties. In another example embodiment of the present disclosure, the indium-containing film does not include or does not substantially include other elements than indium, oxygen, and carbon, but may not be limited thereto. In further another embodiment of the present disclosure, the indium-containing film does not include or does not substantially include other elements than indium, oxygen, and less than about 1 at % carbon, but may not be limited thereto.

In an example embodiment of the present disclosure, the indium-containing film may be formed by chemical vapor deposition or atomic layer deposition, but may not be limited thereto.

In an example embodiment of the present disclosure, the substrate may include a glass, silicon, silicon oxide, or a polymer, but may not be limited thereto.

The indium-containing film in accordance with the first aspect of the present disclosure may include all of described contents regarding the method for forming the indium-containing film in accordance with the first aspect of the present disclosure, but it is omitted for convenience.

In an example embodiment of the present disclosure, there is provided the indium-containing oxide film, which is formed by reacting the gas containing the indium precursor which is a liquid at a room temperature with the oxygen-containing gas prepared using chemical vapor deposition or atomic layer deposition, wherein the indium precursor includes a member selected from the group consisting of bis(trimethylsilyl)aminodiethylindium [(CH₃CH₂)₂InN[Si(CH₃)₃]₂; Et₂InN(TMS)₂], dimethyl(3-dimethylaminopropyl)indium [(CH₃)₂In(CH₂)₃N(CH₃)₂; Me₂In(CH₂)₃NMe₂], and wherein the resistivity of provided the indium-containing oxide film is about 2×10⁻⁵ Ω·cm or less. For example, the indium-containing oxide film has a carrier concentration of about 3×10²¹ cm⁻³ or higher.

In a second aspect of the present disclosure, there is provided a substrate including the indium-containing film in accordance with the first aspect.

In an example embodiment of the present disclosure, the indium-containing film may include an indium-containing oxide film. For example, the indium-containing oxide film includes an indium oxide.

In an example embodiment of the present disclosure, the substrate includes a glass, silicon, silicon oxide, or a polymer, but may not be limited thereto.

In an example embodiment of the present disclosure, the substrate consists of or substantially consists of the indium-containing film in accordance with the first aspect

In an example embodiment of the present disclosure, the indium-containing film consists of or substantially consists of an indium-containing oxide film. For example, the indium-containing oxide film consists of or substantially consists of an indium oxide.

In an example embodiment of the present disclosure, a resistivity of the indium-containing film or the indium-containing oxide film may be at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In a third aspect of the present disclosure, there is provided an indium-containing film having a resistivity of about 2×10⁻⁵ Ω·cm or less.

In an example embodiment of the present disclosure, the indium-containing film may include an indium-containing oxide film, but may not be limited thereto. For example, the indium-containing oxide film includes an indium oxide.

In an example embodiment of the present disclosure, the indium-containing film consists of or substantially consists of an indium-containing oxide film. For example, the indium-containing oxide film consists of or substantially consists of an indium oxide.

In an example embodiment of the present disclosure, a resistivity of the indium-containing film or the indium-containing oxide film may be, for example, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In a fourth aspect of the present disclosure, there is provided a film consisting of or substantially consisting of an indium compound, which has a resistivity of about 1×10⁻⁴ Ω·cm or less.

In an example embodiment of the present disclosure, the film consists of or substantially consists of an indium-containing oxide such as an indium oxide.

In an example embodiment of the present disclosure, a resistivity of the film consisting of or substantially consisting of the indium compound or the film consisting of or substantially consisting of the indium-containing oxide such as an indium oxide may be at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In an example embodiment of the present disclosure, there is provided the film consisting of or substantially consisting of the indium-containing oxide such as an indium oxide, which is formed by reacting the gas containing the indium precursor which is a liquid at a room temperature with the oxygen-containing gas prepared using chemical vapor deposition or atomic layer deposition, wherein the indium precursor includes a member selected from the group consisting of bis(trimethylsilyl)aminodiethylindium [(CH₃CH₂)₂InN[Si(CH₃)₃]₂; Et₂InN(TMS)₂], dimethyl(3-dimethylaminopropyl)indium [(CH₃)₂In(CH₂)₃N(CH₃)₂; Me₂In(CH₂)₃NMe₂], and wherein the resistivity of provided the indium-containing oxide film is about 2×10⁻⁵ Ω·cm or less. For example, the film consisting of the indium-containing oxide has a carrier concentration of about 3×10²¹ cm⁻³ or higher.

In a fifth aspect of the present disclosure, there is provided a composition for forming an indium-containing film, including an indium precursor.

In an example embodiment of the present disclosure, the indium precursor is a liquid at a room temperature.

In an example embodiment of the present disclosure, the indium precursor includes a member selected from the group consisting of bis(trimethylsilyl)aminodiethylindium, dimethyl(3-dimethylaminopropyl)indium, and combinations thereof, but may not be limited thereto.

In an example embodiment of the present disclosure, the composition is used for forming the indium-containing film by chemical vapor deposition or atomic layer deposition.

In an example embodiment of the present disclosure, the indium-containing film may include an indium-containing oxide film. For example, the indium-containing oxide film includes an indium oxide.

In an example embodiment of the present disclosure, the indium-containing film consists of or substantially consists of an indium-containing oxide film. For example, the indium-containing oxide film consists of or substantially consists of an indium oxide.

In an example embodiment of the present disclosure, a resistivity of the indium-containing film or the indium-containing oxide film may be at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁶ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In a sixth aspect of the present disclosure, there is provided a composition for forming an indium-containing film comprising bis(trimethylsilyl)aminodiethylindium.

In an example embodiment of the present disclosure, the composition is used for forming the indium-containing film by chemical vapor deposition or atomic layer deposition.

In an example embodiment of the present disclosure, the indium-containing film may include an indium-containing oxide film. For example, the indium-containing oxide film includes an indium oxide.

In an example embodiment of the present disclosure, the indium-containing film consists of or substantially consists of an indium-containing oxide film. For example, the indium-containing oxide film consists of or substantially consists of an indium oxide.

In an example embodiment of the present disclosure, a resistivity of the indium-containing film or the indium-containing oxide film may be at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In an example embodiment of the present disclosure, a resistivity of the indium-containing film consisting of or substantially consisting of an indium-containing oxide film, or the indium-containing oxide film consisting of or substantially consisting of an indium oxide may be at most or less than about 1×10⁻⁴ Ω·cm, for example, at most or less than about 8×10⁻⁵ Ω·cm, at most or less than about 6×10⁻⁵ Ω·cm, at most or less than about 4×10⁻⁵ Ω·cm, at most or less than about 2×10⁻⁵ Ω·cm, at most or less than about 1×10⁻⁵ Ω·cm, at most or less than about 8×10⁻⁶ Ω·cm, at most or less than about 6×10⁻⁶ Ω·cm, at most or less than about 4×10⁻⁶ Ω·cm, at most or less than about 2×10⁻⁶ Ω·cm, or at most or less than about 1×10⁻⁶ Ω·cm, but may not be limited thereto.

In an example embodiment of the present disclosure, the indium-containing film does not include or does not substantially include Si derived from the indium precursor. Conventionally, when an indium precursor including Si element reacts with the oxygen-containing gas such as O₂, O₃, H₂O₂, H₂O and the like, it is typically expected to form a film including Indium, carbon, silicon and nitrogen. In this regard, Si included in the indium precursor reacts with the oxygen-containing gas to form SiO₂ which is an insulator so that it is conventionally expected that the film including SiO₂ has high electrical resistance, and thus low electrical conductivity. However, although the indium precursor used in embodiments of the present disclosure includes Indium, carbon, hydrogen, silicon and nitrogen elements, the indium-containing film produced by using the indium precursor does not include or does not substantially include Si derived from the indium precursor, which is a very significant result, unexpected in the art. Furthermore, the indium-containing film of the present disclosure includes very low carbon content. Conventionally, a film including carbon has poor electrical properties. Therefore, the indium-containing film of the present disclosure has unexpected superior electrical properties. In another example embodiment of the present disclosure, the indium-containing film does not include or does not substantially include other elements than indium, oxygen, and carbon, but may not be limited thereto. In further another embodiment of the present disclosure, the indium-containing film does not include or does not substantially include other elements than indium, oxygen, and less than 1 at % carbon, but may not be limited thereto.

### MODE FOR CARRYING OUT THE INVENTION

Hereinafter, the present disclosure will be explained in detail with reference to examples. However, the present disclosure is not limited thereto.

### EXAMPLES

### Example 1

### Formation of Indium Oxide Film by Atomic Layer Deposition Using Et₂InN(TMS)₂

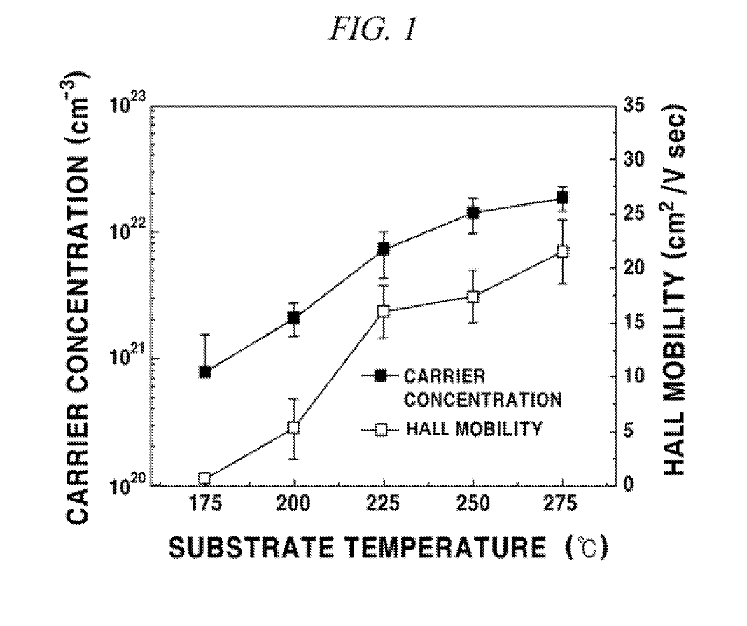

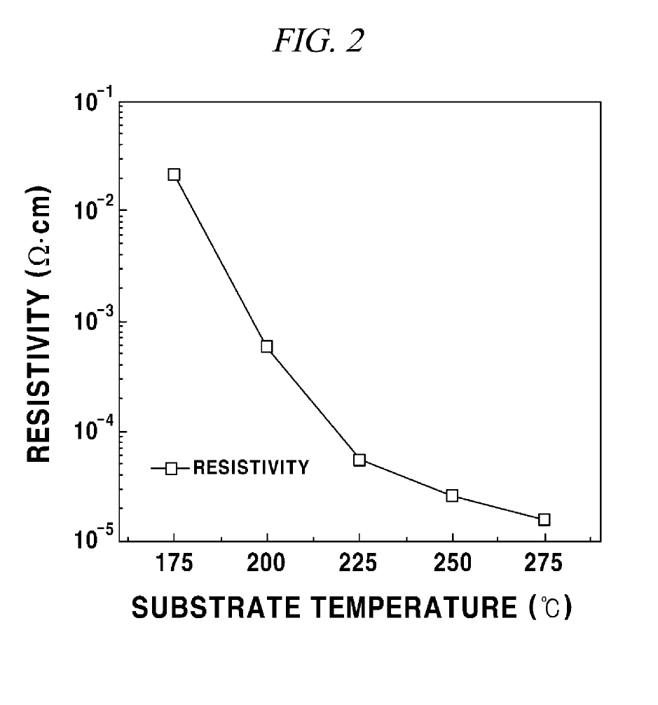

A gas of Et₂InN(TMS)₂ which is a liquid at a room temperature, and H₂O gas were alternately brought into contact with a substrate. In the present example, each of a silicon substrate and a silicon substrate on which a silicon oxide film is formed was used. The both substrates had the same film growth rate per atomic layer deposition gas supply cycle. The substrate was maintained at a temperature of from 100° C. to 275° C. Et₂InN(TMS)₂ was vaporized at a temperature of from 30° C. to 60° C. By using a typical time division atomic layer deposition apparatus, the gas of Et₂lnN(TMS)₂, an inert gas, H₂O gas, and an inert gas were repeatedly supplied in sequence for 1 second, 10 seconds, 1 second, and 10 seconds, respectively, to a region where the substrate was placed. The inert gas may be employed from those known in the art, such as N₂ gas, Ar gas, He gas, or combined gases thereof. In the present example, Ar gas was used as the inert gas. In the temperature range of the substrate from 175° C. to 225° C., even when a supplied amount of Et₂InN(TMS)₂ was increased, a film growth rate per atomic layer deposition gas supply cycle (growth-per-cycle, GPC) was constant in the range of from 0.067 nm/cycle to 0.069 nm/cycle. On the silicon oxide film substrate heated at temperatures of 175° C., 200° C., 225° C., 250° C., and 275° C., an indium oxide film was formed to a thickness of from about 30 nm to about 35 nm, and a Hall mobility, a carrier concentration, and a resistivity were obtained by measuring a Hall effect as shown in FIG. 1 and FIG. 2. In the present example, a resistivity of the indium oxide film formed at 275° C. was 1.6×10⁻⁵ Ω·cm, which means a high conductivity equivalent to that of a commonly used transparent electrode formed by a conventional sputtering method. As a result analyzed by X-ray photoelectron spectroscopy (XPS), 4.3 at % carbon was detected from the indium oxide film formed at 175° C. in addition to indium and oxygen, and 0.3 at % carbon was detected from the indium oxide film formed at 200° C. in addition to indium and oxygen. No carbon and no Si was detected from the indium oxide films formed at 250° C. and 275° C. respectively.

### Example 2

### Formation of Indium Oxide Film by Atomic Layer Deposition Using Me₂In(CH₂)₃NMe₂

A gas of Me₂In(CH₂)₃NMe₂ which is a liquid at a room temperature, and H₂O gas were brought into contact with a substrate. In the present example, each of a silicon substrate and a silicon substrate on which a silicon oxide film is formed was used. The both substrates had the same film growth rate per atomic layer deposition gas supply cycle. The substrate was maintained at a temperature of from 100° C. to 275° C. Me₂In(CH₂)₃NMe₂ was vaporized at a room temperature. By using a typical time division atomic layer deposition apparatus, the gas of Me₂In(CH₂)₃NMe₂, an inert gas, a H₂O gas, and an inert gas were repeatedly supplied in sequence for 1 second, 10 seconds, 1 second, and 10 seconds, respectively, to a region where the substrate was placed. The inert gas may be employed from those known in the art, such as N₂ gas, Ar gas, He gas, or combinations thereof. In the present example, an Ar gas was used as the inert gas. At the temperature of the substrate of 275° C., even when a supplied amount of the Me₂In(CH₂)₃NMe₂ was increased, a film growth rate per atomic layer deposition gas supply cycle (growth-per-cycle, GPC) was constant at 0.059 nm/cycle. At a temperature of the substrate of 225° C. or less, an indium oxide film was hardly formed (GPC<0.01 nm/cycle). As a result of measurement of a Hall effect of the indium oxide film formed on the silicon oxide film heated at a temperature of 275° C., a resistivity was 9.2×10⁻⁵ Ω·cm, a Hall mobility was 0.35 cm²/V·sec, and a carrier concentration was 1.7×10²³.

### Example 3

### Formation of IGZO Film by Atomic Layer Deposition Using Et₂InN(TMS)₂

Et₂InN(TMS)₂ gas, trimethylgallium (TMG) gas, diethylzinc (DEZ) gas, and H₂O gas were alternately brought into contact with a substrate. The substrate was maintained at a temperature of from room temperature to 500° C. or less, more preferably from 50° C. to 200° C. or less, and still more preferably from 50° C. to 150° C. In an IGZO film grown by regulating the order and the ratio of a Gas supply cycle 1 in which Et₂InN(TMS)₂ gas, an inert gas, H₂O gas, and an inert gas are brought into contact in sequence with the substrate; a Gas supply cycle 2 in which TMG gas, an inert gas, H₂O gas, and an inert gas are brought into contact in sequence with the substrate; and a Gas supply cycle 3 in which DEZ gas, an inert gas, H₂O gas, and an inert gas are brought into contact in sequence with the substrate, a metal ratio can be regulated. By way of example, the IGZO film formed by repeating a super cycle of the Gas supply cycle 1—Gas supply cycle 2—Gas supply cycle 1—Gas supply cycle 3is higher in in content than that of the IGZO film formed by repeating a super cycle of the Gas supply cycle 1—Gas supply cycle 2—Gas supply cycle 3was. As the substrate, any one of those known in the art, such as a glass, silicon, or a polymer may be used. The inert gas may be employed from those known in the art, such as N₂ gas, Ar gas, He gas, or combinations thereof. Instead of the H₂O gas, a H₂O₂ gas, an oxygen (O₂) gas, and an ozone (O₃) gas may be used as oxygen sources for forming an oxide.

### Example 4

### Formation of Indium Oxide Film by Chemical Vapor Deposition Using Et₂InN(TMS)₂

Et₂InN(TMS)₂ gas and H₂O gas were simultaneously supplied to a substrate so as to form an indium oxide film on the substrate. The substrate can be maintained at a temperature of from room temperature to 500° C. or less, more preferably from 50° C. to 200° C. or less, and still more preferably from 50° C. to 150° C. After a temperature of the substrate was set, Et₂InN(TMS)₂ gas was supplied using a carrier gas in a chemical vapor deposition apparatus where the substrate was placed, and at the same time, H₂O gas was supplied. The carrier gas may be employed from those known in the industry, such as N₂ gas, Ar gas, He gas, or combinations thereof. As the substrate, any one of those known in the industry, such as a glass or silicon may be used. The inert gas may be employed from those known in the industry, such as N₂ gas, Ar gas, He gas, or combined gases thereof. Instead of the H₂O gas, a H₂O₂ gas, an oxygen (O₂) gas, and an ozone (O₃) gas may be used as oxygen sources for forming an oxide.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. An indium-containing film, formed by reacting a gas containing an indium precursor with an oxygen-containing gas on a substrate.

2. The indium-containing film according to claim 1,
wherein the indium-containing film includes a indium-containing oxide film.

3. The indium-containing film according to claim 1,
wherein a resistivity of the indium-containing oxide film is 1×10⁻⁴ Ω·cm or less.

4. The indium-containing film according to claim 1,
wherein the substrate includes a glass, silicon, silicon oxide, or a polymer.

5. The indium-containing film according to claim 1,
wherein the indium precursor is a liquid at a room temperature.

6. The indium-containing film according to claim 1,
wherein the indium precursor includes a member selected from the group consisting of bis(trimethylsilyl)aminodiethylindium, dimethyl(3-dimethylaminopropyl)indium, and combinations thereof.

7. The indium-containing film according to claim 1,
wherein the indium-containing film does not include Si derived from the indium precursor.

8. A substrate comprising the indium-containing film of claim 1.

9. An indium-containing film, which has a resistivity of 2×10⁻⁵ Ω·cm or less.

10. The indium-containing film according to claim 9,
wherein the indium-containing film includes an indium-containing oxide film.

11. The indium-containing film according to claim 9,
wherein the indium-containing film substantially consists of an indium-containing oxide film.

12. A film substantially consisting of an indium compound, which has a resistivity of 1×10⁻⁴ Ω·cm or less.

13. The film consisting of the indium compound according to claim 12,
wherein the indium compound is an indium-containing oxide.

14. The film consisting of the indium compound according to claim 12,
wherein the resistivity of the film is 4×10⁻⁵ Ω·cm or less.

15. A composition for forming an indium-containing film, comprising an indium precursor which is a liquid at room temperature.

16. The composition for forming the indium-containing film according to claim 15,
wherein a resistivity of the indium-containing film is 1×10⁻⁴ Ω·cm or less.

17. The composition for forming the indium-containing film according to claim 15,
wherein the indium compound includes a member selected from the group consisting of bis(trimethylsilyl)aminodiethylindium, dimethyl(3-dimethylaminopropyl)indium, and combinations thereof.

18. The composition for forming the indium-containing film according to claim 15,
wherein the composition is used for forming the indium-containing film by chemical vapor deposition or atomic layer deposition.

19. The composition for forming the indium-containing film according to claim 15,
wherein the indium-containing film does not include Si derived from the indium precursor.

20. The composition for forming the indium-containing film according to claim 15,
wherein the indium-containing film includes an indium-containing oxide film.
